(19) United States
(12) Patent Application Publication
(10) Pub. No.: US 2014/0160689 A1
(43) Pub. Date: Jun. 12, 2014

(54) PACKAGE

(71) Applicant: Electronics and Telecommunications Research Institute, Daejeon (KR)

(72) Inventors: Dong Min KANG, Daejeon (KR); Chull Won Ju, Daejeon (KR); Seong-Il Kim, Daejeon (KR); Sang-Heung Lee, Daejeon (KR); Jong-Won Lim, Daejeon (KR); Hyung Sup Yoon, Daejeon (KR); Jae Kyoung Mun, Daejeon (KR); Eun Soo Nam, Daejeon (KR)

(73) Assignee: Electronics and Telecommunications Research Institute, Daejeon (KR)

(21) Appl. No.: 13/959,666

(22) Filed: Aug. 5, 2013

(30) Foreign Application Priority Data
Dec. 12, 2012 (KR) 10-2012-0144129

(51) Int. Cl. H05K 1/02

(52) U.S. Cl. CPC H05K 1/0213
USPC 361/728

(57) ABSTRACT

A package includes a ground plate, a chip mounting plate disposed at a side of the ground plate and having a top surface lower than a top surface of the ground plate, a chip on the chip mounting plate, a first input/output terminal opposite to the chip mounting plate and disposed at another side of the ground plate, and a second input/output terminal opposite to the ground plate and disposed at a side of the chip mounting plate. The first and second input/output terminals are electrically connected to the chip.

### CROSS-REFERENCE TO RELATED APPLICATIONS

This U.S. non-provisional patent application claims priority under 35 U.S.C. §119 to Korean Patent Application No. 10-2012-0144129, filed on Dec. 12, 2012, the entirety of which is incorporated by reference herein.

### BACKGROUND

The inventive concept relates to a package and, more particularly, to a package for a high power device.

In a package for a high power device, a semiconductor chip may be bonded to a package board by an adhesive. Thus, it may be difficult to exactly bond the semiconductor chip to the package in a regular direction. In a high power device used in a microwave band, many bonding wires may be connected between a package and a chip. Thus, if the direction of the chip is not regular, lengths of the bonding wires of the high power device may become different from each other. As a result, it may be difficult to realize uniform radio frequency (RF) and power characteristics of the high power device. Additionally, loss of the RF and power characteristics of the high power device may be caused.

The chip may be bonded to a metal plate by using, for example, a eutectic bonding process. In this case, a direction of the chip may be missed, such that the lengths of the bonding wires may be different from each other. The missed direction of the chip may cause the loss of the RF and power characteristics of the high power device and may reduce a process yield of manufacture of a package.

### SUMMARY

Embodiments of the inventive concept may provide packages having improved electrical efficiency and improved reliability.

In an aspect, a package may include: a ground plate; a chip mounting plate disposed at a side of the ground plate, the chip mounting plate having a top surface lower than a top surface of the ground plate; a chip mounted on the chip mounting plate; a first input/output terminal opposite to the chip mounting plate and disposed at another side of the ground plate, the first input/output terminal electrically connected to the chip; and a second input/output terminal opposite to the ground plate and disposed at a side of the chip mounting plate, the second input/output terminal electrically connected to the chip.

In an embodiment, a height difference may occur between the top surfaces of the ground plate and the chip mounting plate.

In an embodiment, the package may further include: a first bonding wire electrically connecting the chip to the first input/output terminal; and a second bonding wire electrically connecting the chip to the second input/output terminal.

In an embodiment, a source terminal of the chip may be grounded.

In an embodiment, the package may further include: a third bonding wire electrically connecting the source terminal of the chip to the ground plate.

In an embodiment, the source terminal of the chip may be grounded through a via-electrode.

In an embodiment, the chip mounting plate may include a protrusion protruding upward from the top surface of the chip mounting plate. The protrusion may be adjacent to the second input/output terminal.

In an embodiment, a top surface of the protrusion may be disposed at a level substantially equal to or lower than a level of a top surface of the chip.

### BRIEF DESCRIPTION OF THE DRAWINGS

The inventive concept will become more apparent in view of the attached drawings and accompanying detailed description.

FIG. 1 is a plan view illustrating a package according to embodiments of the inventive concept;

FIGS. 2A and 2B are cross-sectional views taken along a line I-I′ of FIG. 1; and

FIGS. 3A, 3B, and 3C are plan views illustrating structures of chip mounting plates according to embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

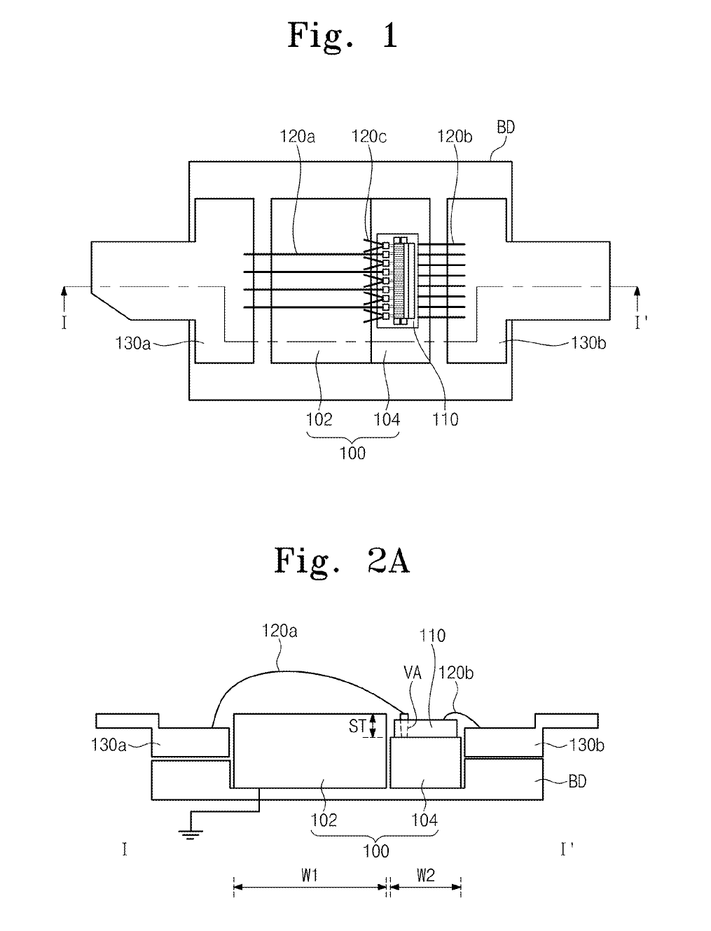

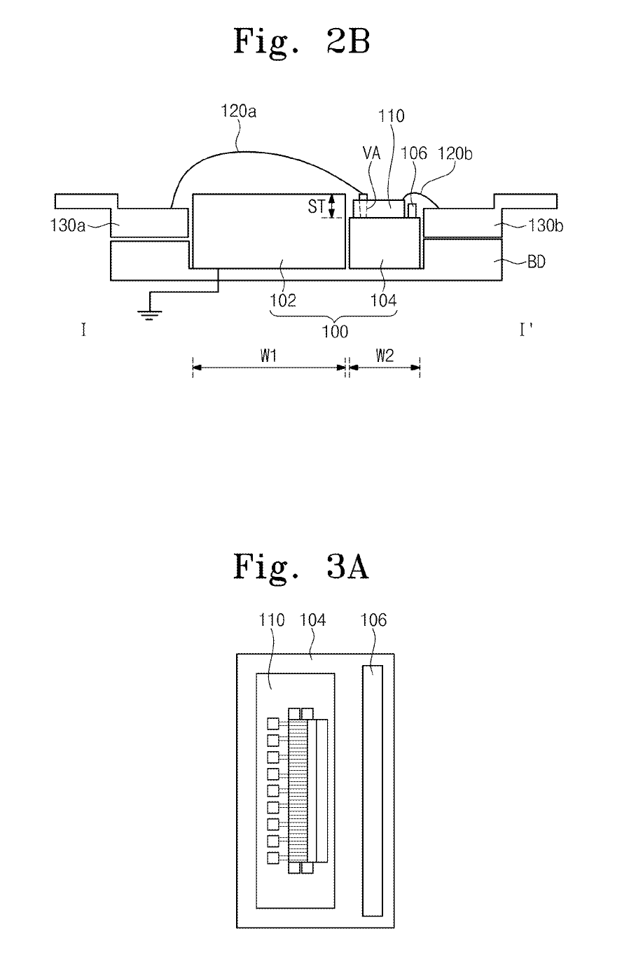

FIG. 1 is a plan view illustrating a package according to embodiments of the inventive concept, and FIG. 2A is a cross-sectional view taken along a line I-I′ of FIG. 1.

Referring to FIGS. 1 and 2A, a package may include a package body BD, a conductive plate 100 disposed in the package body BD, a chip 110, an input terminal 130a, and an output terminal 130b.

The conductive plate 100 may include a ground plate 102 and a chip mounting plate 104. The ground plate 102 and the chip mounting plate 104 may be separated from each other. A top surface of the ground plate 102 may be higher than a top surface of the chip mounting plate 104. Thus, a height difference ST may occur between the ground plate 102 and the chip mounting plate 104 adjacent to each other. For example, the height difference ST may be several tens μm or more.

The ground plate 102 may have a first width W1 and the chip mounting plate 104 may have a second width W2. The second width W2 may be substantially equal to or greater than a width of the chip 110. The first width W1 may be changed depending on a kind of a package.

The chip 110 may include high power devices. The high power devices may amplify a radio frequency (RF) signal inputted through the input terminal 130a.

The chip 110 may be mounted on the chip mounting plate 104. According to some embodiments of the inventive concept, the chip mounting plate 104 has the top surface lower than the top surface of the ground plate 102, thereby generating the height difference ST, as described above. Misalignment between the chip 110 and the chip mounting plate 104 may be prevented by the height difference ST.

The chip 110 may be mounted on the chip mounting plate 104 by a eutectic bonding process. Two or more kinds of alloy elements may be melted and then may be uniformly merged with each other. The melted liquid including the alloy elements may be slowly cooled and then the melted liquid may be converted into two or more kinds of crystals simultaneously at a specific temperature, so that a mixture of fine crystal particles may be generated. The eutectic corresponds to the mixture of the fine crystal particles.

The input terminal 130a may be disposed at a side of the conductive plate 100. The input terminal 130a may be separated from the conductive plate 100. The input terminal 130a may be electrically connected to the chip 110 by at least one first bonding wire 120a.

The output terminal 130b may be disposed at another side of the conductive plate 100. The output terminal 130b may be opposite to the input terminal 130a with the conductive plate 100 therebetween. The output terminal 130b may be separated from the conductive plate 100. The output terminal 130b may be electrically connected to the chip 110 by at least one second bonding wire 120b.

The RF signal may be inputted through the input terminal 130a from an external system, and then the RF signal may be transmitted into the chip 110 through the first bonding wire 120a. The chip 110 may amplify the RF signal. The RF signal amplified in the chip 110 may be transmitted to the output terminal 130b through the second bonding wire 120b.

The first width W1 of the ground plate 102 may be controlled to change of a length of the first bonding wire 120a. Additionally, the second width W2 of the chip mounting plate 104 may be controlled to change a length of the second bonding wire 120b. The lengths of the first and second bonding wires 120a and 120b are changed to control input/output impedances of the high power device in the chip 110. Since the input/output impedances of the high power device are controlled, an adjustment characteristic of high power input/output may be changed. In other embodiments, the input/output impedances of the high power device may be controlled by thicknesses and/or the number of the first and second bonding wires 120a and 120b.

A source terminal of the chip 110 may be grounded. In some embodiments, the source terminal of the chip 110 may be electrically connected to the ground plate 102 through a third bonding wire 120c. In other embodiments, the source terminal of the chip 110 may be grounded through a via-electrode VA. In this case, the third bonding wire 120c may be omitted.

According to embodiments of the inventive concept, the misalignment of the chip 110 mounted on the chip mounting plate 104 may be prevented by the height difference ST between the chip mounting plate 104 and the ground plate 102. Thus, the lengths of the first bonding wires 120a connected to the input terminal 130a may be substantially uniform, and the lengths of the second bonding wires 120b connected to the output terminal 130b may be substantially uniform. As a result, a RF characteristic of the chip 110 including the high power device may be substantially uniform. Additionally, a yield characteristic of the package having the uniform RF characteristic may be improved.

Furthermore, the first width W1 of the ground plate 102 and/or the second width W2 of the chip mounting plate 104 may be controlled to control the impedances of the high power device, such that the adjustment characteristic of the high power input/output may be variously controlled.

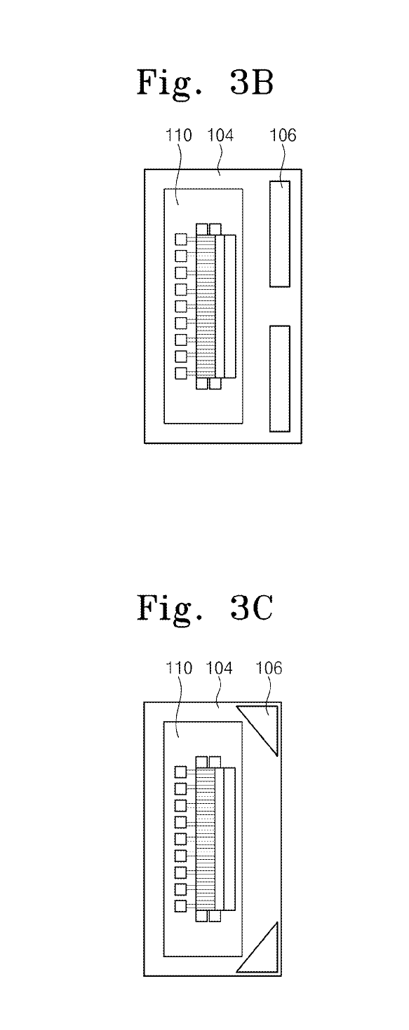

FIG. 1 is a plan view illustrating a package according to embodiments of the inventive concept, and FIG. 2B is a cross-sectional view taken along a line I-I′ of FIG. 1. FIGS. 3A, 3B, and 3C are plan views illustrating structures of chip mounting plates according to embodiments of the inventive concept.

Referring to FIGS. 1 and 2B, a package may include a package body BD, a conductive plate 100 disposed in the package body BD, a chip 110, an input terminal 130a, and an output terminal 130b.

The conductive plate 100 may include a ground plate 102 and a chip mounting plate 104. The ground plate 102 and the chip mounting plate 104 may have a height difference ST. For example, the height difference ST may be several tens μm or more.

The chip mounting plate 104 may include a protrusion 106 protruding upward from an edge of a top surface of the chip mounting plate 104. A top surface of the protrusion 106 may be disposed at a level substantially equal to or lower than a level of a top surface of the chip 110.

In some embodiments, as illustrated in FIG. 3A, the protrusion 106 may be opposite to the ground plate 102 with the chip 110 therebetween. The protrusion 106 may have a linear shape extending in an extending direction of the chip 110.

In other embodiments, as illustrated in FIG. 3B, the protrusion 106 may be disposed to be opposite to the ground plate 102 with the chip 110 therebetween. The protrusion 106 may have a linear shape extending in the extending direction of the chip 100. Here, the protrusion 106 may be cut to be divided into sub-protrusions having bar shapes. The sub-protrusions may be arranged in the extending direction of the chip 110.

In still other embodiments, as illustrated in FIG. 3C, the protrusion 106 may be disposed to be opposite to the ground plate 102 with the chip 110 therebetween. The protrusion 106 may be disposed at a side of each of both ends of the chip 110. The protrusion 106 may have a trilateral shape in a plan view.

The protrusion 106 is disposed on the chip mounting plate 104, such that the misalignment of the chip 110 may be more effectively prevented.

The conductive plate 100, the chip 110, the input terminal 130a, and the output terminal 130b of the present embodiment may be the same as or similar to the conductive plate 100, the chip 110, the input terminal 130a, and the output terminal 130b described in FIGS. 1 and 2B. Thus, detail descriptions to the elements 100, 110, 130a, and 130b are omitted.

According to embodiments of the inventive concept, the height difference occurs between the ground plate and the chip mounting plate separated from each other, such that the misalignment of the chip mounted on the chip mounting plate may be prevented. Additionally, the widths of the ground plate and the chip mounting plate may be controlled to change the lengths of the first and second bonding wires. Thus, the impedances of the high power device in the chip may be variously changed.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A package comprising:
a ground plate;
a chip mounting plate disposed at a side of the ground plate, the chip mounting plate having a top surface lower than a top surface of the ground plate;
a chip mounted on the chip mounting plate;
a first input/output terminal opposite to the chip mounting plate and disposed at another side of the ground plate, the first input/output terminal electrically connected to the chip; and
a second input/output terminal opposite to the ground plate and disposed at a side of the chip mounting plate, the second input/output terminal electrically connected to the chip.

2. The package of claim 1, a height difference occurs between the top surfaces of the ground plate and the chip mounting plate.

3. The package of claim 1, further comprising:
a first bonding wire electrically connecting the chip to the first input/output terminal; and
a second bonding wire electrically connecting the chip to the second input/output terminal.

4. The package of claim 1, wherein a source terminal of the chip is grounded.

5. The package of claim 4, further comprising:
a third bonding wire electrically connecting the source terminal of the chip to the ground plate.

6. The package of claim 4, wherein the source terminal of the chip is grounded through a via-electrode.

7. The package of claim 1, wherein the chip mounting plate includes a protrusion protruding upward from the top surface of the chip mounting plate,
wherein the protrusion is adjacent to the second input/output terminal.

8. The package of claim 7, wherein a top surface of the protrusion is disposed at a level substantially equal to or lower than a level of a top surface of the chip.
